(19) United States
(12) Patent Application Publication
(10) Pub. No.: US 2014/0319363 A1
(43) Pub. Date: Oct. 30, 2014

(54) RADIATION DETECTOR

(71) Applicant: KONINKLIJKE PHILIPS N.V., EINDHOVEN (NL)

(72) Inventors: Klaus Juergen Engel, Veldhoven (NL); Christoph Herrmann, Aachen (DE)

(21) Appl. No.: 14/362,139

(22) PCT Filed: Dec. 12, 2012
(86) PCT No.: PCT/IB2012/057212

§ 371 Date: Jun. 2, 2014

Related U.S. Application Data
(60) Provisional application No. 61/569,833, filed on Dec. 13, 2011.

(51) Int. Cl. H01L 27/146; G01T 1/24

(52) U.S. Cl. CPC H01L 27/14605; G01T 1/24; H01L 27/14659
USPC 250/370.01; 257/428

(57) ABSTRACT

The present invention relates to radiation detector (2) comprising a radiation sensitive semiconductor element (10) generating electron-hole pairs in response to an irradiation with radiation (3), an anode electrode(20) arranged on a first surface (11) of the semiconductor element (10) facing away from the radiation, said anode electrode (20) being segmented into anode segments (21) representing anode pixels, wherein anode gaps (22) are arranged between said anode segments (21), a cathode electrode (30) arranged on a second surface (12) of the semiconductor element (10) opposite the first surface (11) and facing the radiation (3), said cathode electrode (30) being segmented into first and second cathode segments (31, 32), wherein said first cathode segments (31) are substantially arranged opposite said anode segments (21) and said second cathode segments (32) are substantially arranged opposite said anode gaps (22), and a cathode terminal (41, 42) providing electrical connections to said first cathode segments (31) and said second cathode segments (32) for coupling different electrical potentials to said first and second cathode segments (31, 32). By such an arrangement charge sharing can be effectively reduced.

### FIELD OF THE INVENTION

The present invention relates to a radiation detector and a radiation detection apparatus, in particular for detection of X-ray and gamma radiation.

### BACKGROUND OF THE INVENTION

Energy resolving detectors for X-ray and gamma radiation based on direct conversion materials, as for example CdTe or CZT, has been proven as an efficient way to measure photon energies. Direct conversion X-ray and gamma ray detectors typically comprise a layer of semiconducting material with metal electrodes on opposing surfaces between which a voltage is supplied. Incident X-ray photons produce a large number of electron-hole pairs almost proportional to the absorbed photon energy. Due to the electric field, the holes and electrons drift in opposite directions until they are collected by the metal electrodes. Usually a continuous metal electrode is used on the surface through which the photons are incident (typically used as cathode), and an array of pixel electrodes on the opposite surface (typically used as anode pixels). In this geometry, position and energy of an absorbed photon can be determined from the current pulse induced on the corresponding pixel anode as described in K. J. Engel and C. Herrmann, Simulation of one-dimensionally polarized X-ray semiconductor detectors, Proceedings of SPIE 7961, 79610W (2011).

The drift motion of electrons is overlaid by diffusion, which causes an extension of the electron cloud with time. If the cloud is located near the border between neighbouring pixels, it happens that a part of the cloud is collected by one pixel and another part of the cloud by the neighbouring pixel, a process which is well-known as “charge sharing”. In result, in both pixels a count is triggered, each of them indicating a (more or less random) part of the original charge such that the original energy information gets lost.

### SUMMARY OF THE INVENTION

It is an object of the present invention to provide a radiation detector and a radiation detection apparatus in which the above described charge sharing is reduced.

In a first aspect of the present invention a radiation detector is presented comprising:

a radiation sensitive semiconductor element generating electron-hole pairs in response to an irradiation with radiation,

an anode electrode arranged on a first surface of the semiconductor element facing away from the radiation, said anode electrode being segmented into anode segments representing anode pixels, wherein anode gaps are arranged between said anode segments,

a cathode electrode arranged on a second surface of the semiconductor element opposite the first surface and facing the radiation, said cathode electrode being segmented into first and second cathode segments, wherein said first cathode segments are substantially arranged opposite said anode segments and said second cathode segments are substantially arranged opposite said anode gaps, and

a cathode terminal providing electrical connections to said first cathode segments and said second cathode segments for coupling different electrical potentials to said first and second cathode segments.

In a further aspect of the present invention a radiation detection apparatus is presented comprising:

a radiation detector as proposed according to the present invention, and

a voltage source coupled to said cathode terminal for coupling different electrical potentials to said first and second cathode segments.

Preferred embodiments of the invention are defined in the dependent claims. It shall be understood that the claimed radiation detection apparatus has similar and/or identical preferred embodiments as the claimed radiation detector and as defined in the dependent claims.

The present invention is based on the idea to use a segmented cathode to reduce the problem of charge sharing. The cathode segments are held on different electric potentials such that a non-homogeneous electric field exists near the cathode directly above pixel border zones (i.e. above the anode gaps) such that generated electron clouds get an additional drift component towards a pixel centre (i.e. towards the centre of an anode segment). In result, the centre of gravity of each cloud is found closer to the corresponding pixel centre, and the charge sharing with the neighbouring pixel(s) is reduced.

It shall be noted that the terms “anode” and “cathode” and the functions of these elements may also be exchanged if a material is used for the semiconductor element where the signal generation with holes is more efficient than the signal generation with electrons. In other words, i.e. the same geometry is used but a different polarity of the electrodes (cathodes and anodes) is used. Hence, in case of using such a semiconductor element the claims directed to the radiation detector and the radiation detection apparatus shall be understood as covering a detector and an apparatus where anode and cathode are exchanged, i.e. the anode is facing the radiation and the cathode is arranged on the opposite side of the semiconductor element.

According to a preferred embodiment said first cathode segments are arranged as an array of first cathode segments. Preferably, the anode segments are arranged as an array as well, preferably of the same structure as the array of the first cathode segments. This embodiment provides a regular arrangement where single cathode and anode segments can be addresses in a simple manner.

According to another embodiment said first cathode segments have substantially the same form in directions parallel to the second surface than said anode segments.

There are different embodiments for implementing said cathode terminal. In one embodiment said cathode terminal comprises a first cathode terminal coupled to said first cathode segments and a second cathode terminal coupled to said second cathode segments for coupling different electrical potentials to said first and second cathode terminals.

In another embodiment the cathode terminal may be a layer to which the semiconductor is bounded by means of e.g. “bump balls” and which provides a routing of electrical connections.

In still another embodiment the cathode terminal provides electrical conductive contacts between two (or more) voltage sources and each cathode segment (or connected groups of cathode segments).

There are different embodiments for addressing the first cathode segments. In a first embodiment said first cathode segments are separated (in particular isolated) from each other and are individually coupled to a first cathode terminal. This embodiment provides the advantage that each cathode segment can be individually provided with an electrical potential, but requires a large number of cathode terminals. In an alternative embodiment said first cathode segments are coupled together in groups, in particular per row or per column, by cathode connection electrodes arranged on said second surface of said semiconductor element, said groups being individually coupled to a first cathode terminal. This embodiment requires a lower number of cathode terminals.

Preferably said second cathode segments are arranged as a grid of second cathode segments. In such an embodiment preferably a single second cathode terminal is sufficient that is coupled to the complete grip. Alternatively, said second cathode segments are coupled together in a single or multiple groups being coupled to one or multiple second cathode terminals enabling a more individual provision of electrical potentials to the second cathode segments.

In a further embodiment said cathode electrode is segmented into at least three cathode segments, wherein said first cathode segments are substantially arranged opposite said anode segments and the further cathode segments are nested around said first cathode segments, and wherein said cathode terminal provides electrical connections to different cathode segments for coupling different electrical potentials to said different cathode segments. Preferably, in an embodiment said cathode terminal comprises at least three cathode terminals being coupled to different cathode segments for coupling different electrical potentials to said different cathode terminals. These embodiments provide further improvements to avoid or suppress charge sharing.

Preferably, said semiconductor element is adapted for generating electron-hole pairs in response to an irradiation with X-ray or gamma radiation. For instance, said semiconductor element is made from an elemental semiconductor material, for example Si or Ge, a binary semiconductor material selected from the IV-group of the periodic system, in particular SiGe or SiC, a binary semiconductor material from the groups III and V of the periodic system, for example InP, GaAs or GaN, a binary semiconductor material from the groups II and VI of the periodic system, for example CdTe, HgTe, CdSe or ZnS, a binary semiconductor material from the groups IV and VI of the periodic system, for example PbO or PbS, a ternary semiconductor material, for example CdZnTe, HgCdTe, or AlGaAs, or a quaternary semiconductor material, for example InGaAsP or InGaAlP.

Advantageously, said radiation detector can further comprise anode gap segments arranged within said anode gaps between adjacent anode segments and an anode terminal providing electrical connections to said anode gap segments for coupling an electrical potential to said anode gap segments, in particular an electrical potential that is more negative (or, in other embodiments, more positive) than the electrical potential of said anode segments. This provides the ability of further steering the electrons towards a pixel anode segment, therefore reducing charge sharing by reducing the number of electrons which traverse the border to neighboring pixels. Furthermore, the capacitive coupling of charges (i.e. holes) within the bulk to the anode segments is reduced such that a more reliable signal is generated by the anode segments.

In general, for the implementation of the anode terminal the same holds that has been explained above for the cathode terminal, i.e. there are various embodiments possible. In one embodiment said anode terminal comprises a first anode terminal coupled to said anode segments and a second anode terminal coupled to said anode gap segments for coupling an electrical potential to said second anode terminals, which is preferably more negative compared to said first anode terminal.

In an embodiment of the radiation detection apparatus said voltage source is adapted for coupling an electrical potential to said second cathode segments that provides a larger voltage difference to said anode electrode than an electrical potential coupled to said first cathode segments. Further, said voltage source is preferably adapted for coupling electrical potentials to said first and second cathode segments having a voltage difference in the range between 10 V and 200 V and/or said voltage source is adapted for coupling electrical potentials to said first and second cathode segments having a voltage difference to the electrical potential of said anode electrode in a typical range between 50 V and 1000 V.

### BRIEF DESCRIPTION OF THE DRAWINGS

These and other aspects of the invention will be apparent from and elucidated with reference to the embodiment(s) described hereinafter. In the following drawings

FIG. 1 shows a cross sectional view of an embodiment of a radiation detection apparatus according to the present invention,

FIG. 2 shows a top view of a first embodiment of a radiation detector according to the present invention,

FIG. 3 shows a top view of a second embodiment of a radiation detector according to the present invention,

FIG. 4 shows a top view of a third embodiment of a radiation detector according to the present invention, and

FIG. 5 shows a cross sectional view of a fourth embodiment of a radiation detector according to the present invention.

### DETAILED DESCRIPTION OF THE INVENTION

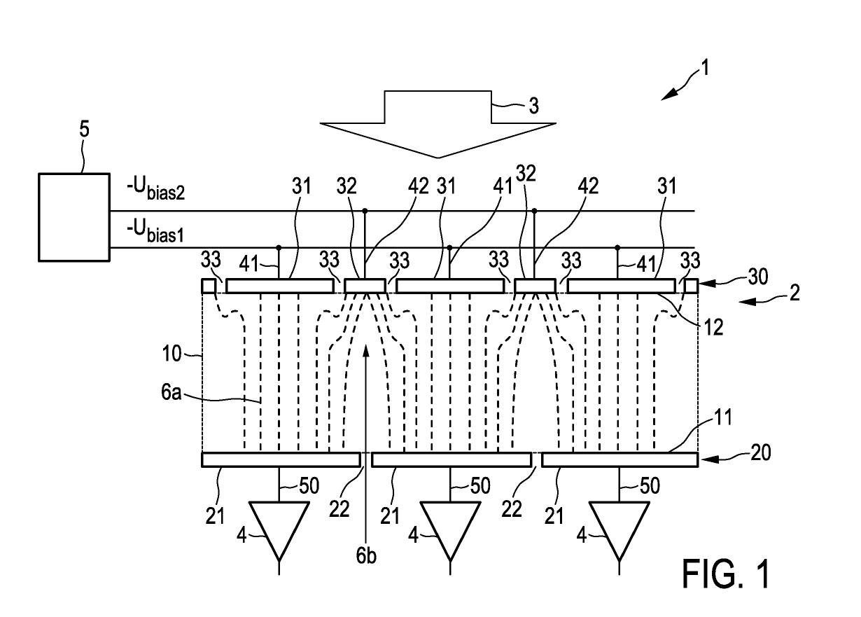

FIG. 1 shows a cross sectional view of an embodiment of a radiation detection apparatus 1 according to the present invention including a radiation detector 2, with a viewing direction perpendicular to the direction of radiation 3 (e.g. X-ray or gamma radiation), which is incident through the plane in which the cathode segments are arranged. FIG. 2 shows a first embodiment of a radiation detector 2 in a top view onto the cathode segments along the direction of incident radiation 3.

As shown in FIGS. 1 and 2 the proposed radiation detector 2 comprises a radiation sensitive semiconductor element 10 generating electron-hole pairs in response to an irradiation with said radiation 3. Such a semiconductor element 10 is generally known in the art and may be made from an elemental semiconductor material, in particular Si or Ge, a binary semiconductor material selected from the IV-group of the periodic system, in particular SiGe or SiC, a binary semiconductor material from the groups III and V of the periodic system, for example InP, GaAs or GaN, a binary semiconductor material from the groups II and VI of the periodic system, for example CdTe, HgTe, CdSe or ZnS, a binary semiconductor material from the groups IV and VI of the periodic system, for example PbO or PbS, a ternary semiconductor material, for example CdZnTe, HgCdTe, or AlGaAs, or a quaternary semiconductor material, for example InGaAsP or InGaAlP. In other embodiments the semiconductor material may be selected which provides a more efficient signal generation by holes than by electrons in which case the same geometry of the radiation detector can be used but with a different polarity of the electrodes (cathodes, anodes, i.e. with cathodes and anodes exchanged).

The radiation detector 2 further comprises a (metal) anode electrode 20 arranged on a first surface 11 of the semiconductor element 10 facing away from the radiation 3. Said anode electrode 20 is segmented into anode segments 21 representing anode pixels, wherein electrode-free (i.e. non-metalized) anode gaps 22 are arranged between said anode segments 21.

On the opposite surface 12 of the semiconductor element 10 facing the radiation 3 the radiation detector 2 further comprises a (metal) cathode electrode 30. Said cathode electrode 30 is segmented into first cathode segments 31 and second cathode segments 32. Said first cathode segments 31 are substantially arranged opposite said anode segments 21 and said second cathode segments 32 are substantially arranged opposite said anode gaps 22. Between said first and second cathode segments 31, 32 non-metalized cathode gaps 33 are provided for isolation.

Still further cathode terminals 40 are provided comprising a first cathode terminal 41 coupled to said first cathode segments 31 and a second cathode terminal 42 coupled to said second cathode segments 32 for coupling different electrical potentials to said first and second cathode terminals 31, 32.

Preferably, anode terminals 50 are provided that are coupled to said anode segments 21 for coupling an electric potential, e.g. ground potential, to the anode segments 21 and/or for coupling signal electronics 4 (e.g. amplifiers, signal processors, storage elements, etc.) of the radiation detection apparatus 1 to the anode segments for signal readout and signal processing.

In this embodiment the square-like first cathode segments 31 correspond in lateral position to the anode segments 21, while the grating-like second cathode segments 32 correspond to the border zones (i.e. the anode gaps 22) between the anode segments 21. Preferably, according to an embodiment of the present invention, the second cathode segments 32 are put to a more negative electrical potential −U_{bias2} compared to that of the first cathode segments 31 which are put on a potential −U_{bias1}, which is preferably achieved by use of a voltage source 5 (or several separate voltage sources) coupled to said cathode terminals 41, 42 for coupling different electrical potentials to said first and second cathode terminals 41, 42.

As shown in FIG. 1 within the largest volume related to a pixel (a pixel being defined by an anode segment 21; pixel borders being indicated in FIG. 1 by dashed lines 23), the electric field lines 6a represent a nearly homogeneous field. In the volume corresponding to pixel borders, the electric field lines 6b are bent especially near the second cathode segments 32 in a way that electrons (mainly following the path of field lines) are pushed towards pixel centres, i.e. the centres of the anode segments 21. This effectively results in a lateral shift of the electron cloud towards a pixel centre if it approaches the anode electrode 20, thus causing less overlap with the neighbouring pixels and therefore causing less charge sharing, which increases the probability that counts are registered with the correct original photon energy.

In the embodiment of the radiation detector 2 shown in FIG. 2 the pixel borders 23 are ideally covered with second cathode segments 32. The first cathode segments 31 need to be individually electrically contacted by first cathode terminals 41 in this embodiment, while generally a single second cathode terminal 42 for contacting said second cathode segments 32 that are all electrically connected is sufficient.

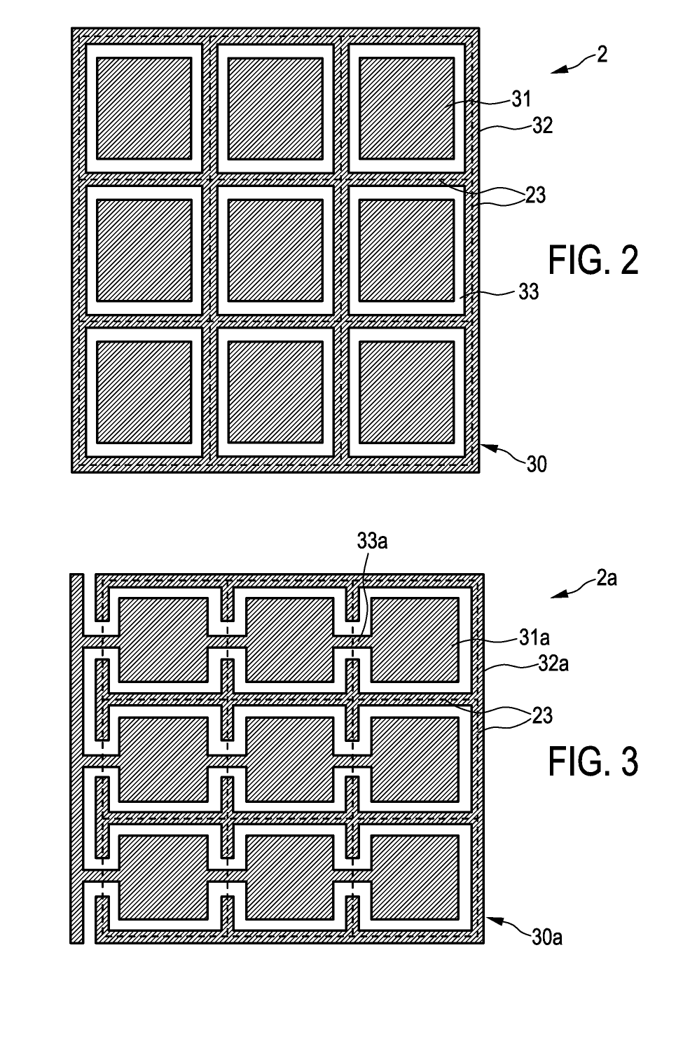

A second embodiment of a radiation detector 2a which may also be used in the radiation detection apparatus 1 is shown in a top view in FIG. 3, showing particularly the segmentation of the cathode electrode 30a. In this embodiment the pixel borders 23 are not ideally covered with second cathode segments 32a. The first cathode segments 31 a are group-wise electrically connected in this embodiment (in the example shown in FIG. 3 along rows) by cathode connection electrodes 33a allowing for a single contact point (i.e. a single first cathode terminal 41) for each group of connected first cathode segments 31a for the bias-voltage supply. The second cathode segments 32a are still all connected but not as a continuous regular grid shown in FIG. 2 but with gaps.

It should be noted that the effect of charge sharing is the bigger the closer to the cathode side the radiation interaction happens, since in this case drift time of the generated electrons toward the pixel anode reaches its maximum so that the electron cloud has the largest amount of time to extend until reaching the pixel anode.

The geometrical sizes of the radiation detector 2, 2a are scalable. Typically, the thickness of a radiation detector 2, 2a is between 0.5 and 5 mm, the pixel sizes (anode segments 21) are between 50 and 2000 μm. Typical anode gaps 22 between anode segments 21 are sized between 20 and 500 μm.

U_{bias1} is typically chosen to generate an electric field between 30 and 500 V/mm. The anode segments 21 are typically on an electric potential of 0 V (or virtual GND).

A typical size of the second cathode segments 32 should correspond to the typical depth of X-ray interaction, i.e. about 50-500 μm, as the zone of bent electric field lines in depth corresponds to the “thickness” of the grating lines of the second cathode segments 32. Accordingly the voltage difference between U_{bias2} and U_{bias1} should be chosen as a best compromise between minimizing the emission current of second cathode segments 32 (which is partly collected by the anode pixels 21) and maximizing the electric field bending around the second cathode segments 32.

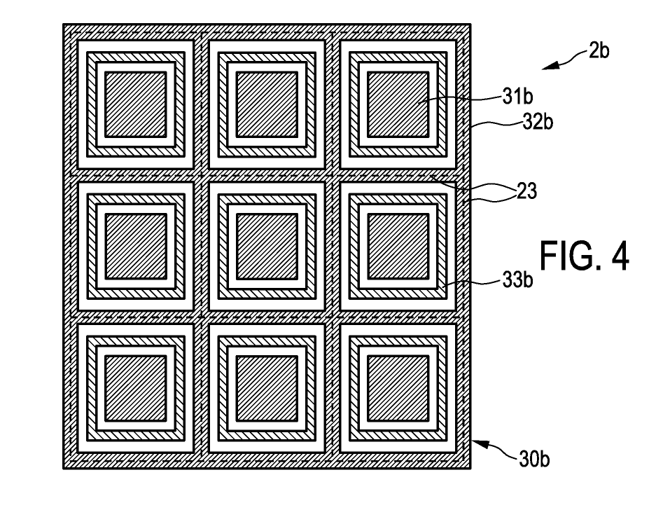

The electric field bending can be optimized by using more than two cathode segmentations, i.e. by using nested cathode segments 31b, 32b, 33b with increasing negative electric potential towards the border zone 23 between pixels as schematically illustrated in FIG. 4 showing a third embodiment of a radiation detector 2b according to the present invention. FIG. 4 particularly shows a segmentation of the cathode electrode 30b, where a second cathode segment 32b and a third cathode segment 33b is arranged around the central first cathode segment 31b.

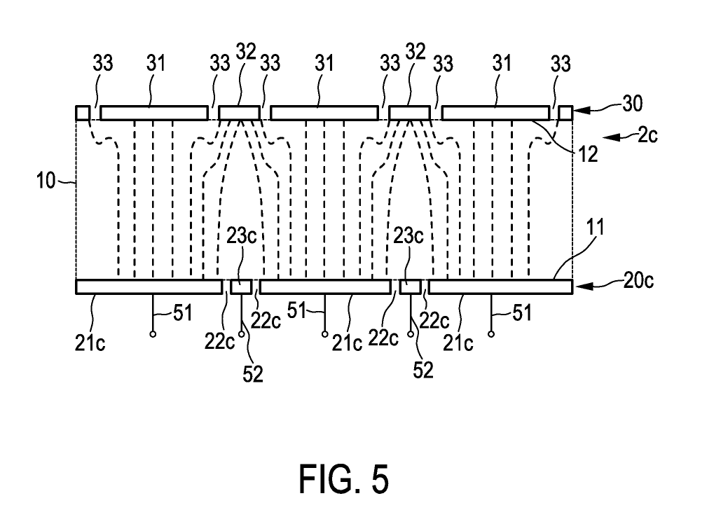

Optionally, the anode segmentation can be further improved, for example by using a well-known steering electrode technology (as e.g. disclosed in U.S. Pat. No. 6,333,504). An embodiment of such a radiation detector 2c in a cross section is shown in FIG. 5. In this embodiment the anode electrode 20c comprises not only the anode segments 21c and the anode gaps 22c, but also anode gap segments 23c arranged within said anode gaps 22c between adjacent anode segments 21c. Further, first anode terminal 51 coupled to said anode segments 21c and a second anode terminal 52 coupled to said anode gap segments 23c are provided for coupling different electrical potentials to said first and second anode terminals 51, 52 such that the electric potential of the anode gap segments 23c is more negative than the electrical potential of the anode segments 21c. This provides the ability of further steering the electrons towards the center of a pixel anode segment which reduces charge sharing with neighboring pixels. Most advantageous is the cooperative steering effect of said second cathode segments 32 with said anode gap segments, where said cathode segments 32 ideally steer the whole electron cloud in an early stage towards the pixel centre, while the steering of the anode gap segments 23c avoid that larger (i.e. outer) parts of the electron cloud (which is expanding with time by diffusion) are collected by neighboring pixels. Furthermore, the capacitive coupling of charges within the bulk to the pixel anode segments is reduced such that a more reliable signal is generated by the pixel anode segments.

Further, generally holds that the more negative potential U_{bias2} may slightly increase the dark current. Thus U_{bias2} should be chosen such that the additional noise on the current signals is acceptable.

The invention is particularly applicable to all sorts of direct conversion detectors, in which electron-hole pairs are generated by photons. More specifically, these photons can be X-ray or gamma photons. One application of the invention is particularly for photon counting detectors in X-ray spectral imaging. Hence the proposed radiation detector apparatus may be included in various kinds of X-ray devices, CT devices or gamma radiation detection devices.

While the invention has been illustrated and described in detail in the drawings and foregoing description, such illustration and description are to be considered illustrative or exemplary and not restrictive; the invention is not limited to the disclosed embodiments. Other variations to the disclosed embodiments can be understood and effected by those skilled in the art in practicing the claimed invention, from a study of the drawings, the disclosure, and the appended claims.

In the claims, the word “comprising” does not exclude other elements or steps, and the indefinite article “a” or “an” does not exclude a plurality. A single element or other unit may fulfill the functions of several items recited in the claims. The mere fact that certain measures are recited in mutually different dependent claims does not indicate that a combination of these measures cannot be used to advantage.

Any reference signs in the claims should not be construed as limiting the scope.

1. A radiation detector comprising:
a radiation sensitive semiconductor element generating electron-hole pairs in response to an irradiation with X-ray or gamma radiation,
an anode electrode arranged on a first surface of the semiconductor element, said anode electrode being segmented into anode segments representing anode pixels, wherein anode gaps are arranged between said anode segments,
a cathode electrode arranged on a second surface of the semiconductor element opposite the first surface, said cathode electrode being segmented into first and second cathode segments, wherein said first cathode segments are substantially arranged opposite said anode segments and said second cathode segments are substantially arranged opposite said anode gaps, and
a cathode terminal providing electrical connections to said first cathode segments and said second cathode segments for coupling different electrical potentials to said first and second cathode segments.

2. The radiation detector as claimed in claim 1, wherein said first cathode segments are arranged as an array of first cathode segments.

3. The radiation detector as claimed in claim 1, wherein said first cathode segments (31) have substantially the same form in directions parallel to the second surface than said anode segments.

4. The radiation detector as claimed in claim 1, wherein said first cathode segments are separated from each other and are individually coupled to a first cathode terminal.

5. The radiation detector as claimed in claim 1, wherein said first cathode segments are coupled together in groups, in particular per row or per column, by cathode connection electrodes arranged on said second surface of said semiconductor element, said groups being individually coupled to a first cathode terminal.

6. The radiation detector as claimed in claim 1, wherein said second cathode segments arranged as a grid of second cathode segments.

7. The radiation detector as claimed in claim 1, wherein said second cathode segments are coupled together in a single or multiple groups being coupled to one or multiple second cathode terminals.

8. The radiation detector as claimed in claim 1, wherein said cathode electrode is segmented into at least three cathode segments, wherein said first cathode segments are substantially arranged opposite said anode segments and the further cathode segments are nested around said first cathode segments, and
wherein said cathode terminal provides electrical connections to different cathode segments for coupling different electrical potentials to said different cathode segments.

9. The radiation detector as claimed in claim 1, wherein said semiconductor element is adapted for generating electron-hole pairs in response to an irradiation with X-ray or gamma radiation.

10. The radiation detector as claimed in claim 1, wherein said semiconductor element is made from an elemental semiconductor material, in particular Si or Ge, a binary semiconductor material selected from the IV-group of the periodic system, in particular SiGe or SiC, a binary semiconductor material from the groups III and V of the periodic system, in particular InP, GaAs or GaN, a binary semiconductor material from the groups II and VI of the periodic system, in particular CdTe, HgTe, CdSe or ZnS, a binary semiconductor material from the groups IV and VI of the periodic system, in particular PbO or PbS, a ternary semiconductor material, in particular CdZnTe, HgCdTe, or AlGaAs or a quaternary semiconductor material, in particular InGaAsP or InGaAlP.

11. The radiation detector as claimed in claim 1, further comprising
anode gap segments arranged within said anode gaps between adjacent anode segments and
an anode terminal providing electrical connections to said anode gap segments for coupling an electrical potential to said anode gap segments, in particular an electrical potential that is more negative than the electrical potential of said anode segments.

12. A radiation detection apparatus comprising:
a radiation detector as claimed in claim 1, and
a voltage source coupled to said cathode terminal for coupling different electrical potentials to said first and second cathode segments.

13. The radiation detection apparatus as claimed in claim 12, wherein said voltage source is adapted for coupling an electrical potential to said second cathode segments that provides a larger voltage difference to said anode electrode than an electrical potential coupled to said first cathode segments.

14. The radiation detection apparatus as claimed in claim 12, wherein said voltage source is adapted for coupling electrical potentials to said first and second cathode segments having a voltage difference in the range between 10 V and 200 V.

15. The radiation detection apparatus as claimed in claim 12, wherein said voltage source is adapted for coupling electrical potentials to said first and second cathode segments having a voltage difference to the electrical potential of said anode electrode in the range between 50 V and 1000 V.

16. A radiation detector comprising:
a radiation sensitive semiconductor element generating electron-hole pairs in response to an irradiation with X-ray or gamma radiation;
a cathode electrode arranged on a first surface of the semiconductor element, said cathode electrode being segmented into cathode segments representing cathode pixels, wherein cathode gaps are arranged between said cathode segments,
an anode electrode arranged on a second surface of the semiconductor element opposite the first surface, said anode electrode being segmented into first and second anode segments, wherein said first anode segments are substantially arranged opposite said cathode segments and said second anode segments are substantially arranged opposite said cathode gaps, and
an anode terminal providing electrical connections to said first anode segments and said second anode segments for coupling different electrical potentials to said first and second anode segments.

17. A radiation detection apparatus comprising:
a radiation detector as claimed in claim 16, and
a voltage source coupled to said anode terminal for coupling different electrical potentials to said first and second anode segments.
